(19) United States
(12) Patent Application Publication
(10) Pub. No.: US 2025/0285811 A1
(43) Pub. Date: Sep. 11, 2025

(54) MULTILAYER CERAMIC CAPACITORS (MLCC) ARRAY AND INTEGRATION WITH ACTIVE DEVICES

(71) Applicant: Murata Manufacturing Co., Ltd., Kyoto (JP)

(72) Inventors: David M. GIULIANO, Bedford, NH (US); Kouassi Sebastien KOUASSI, San Diego, CA (US)

(21) Appl. No.: 18/600,443

(22) Filed: Mar. 8, 2024

(51) Int. Cl. H01G 4/38; H01G 4/224; H01L 21/48; H01L 23/00; H01L 23/498

(52) U.S. Cl. CPC H01G 4/38; H01G 4/224; H01L 21/4853; H01L 21/486; H01L 23/49811; H01L 23/49838; H01L 24/08; H01L 24/13; H01L 24/16; H01L 24/32; H01L 24/73; H01L 24/92; H01L 23/49827; H01L 2224/08225; H01L 2224/13147; H01L 2224/16227; H01L 2224/32225; H01L 2224/73204; H01L 2224/92125

(57) ABSTRACT

Packages and methods for fabricating a module with reduced area, including forming a resin-based substrate by forming a resin on a plurality of multilayer ceramic capacitors (MLCCs). Packages and methods for fabricating a module with reduced area include forming a MLCC-based substrate by forming a resin on a plurality of MLCCs, wherein each MLCC of the plurality of MLCCs directly contacts another MLCC.

### TECHNICAL FIELD

The present disclosure relates generally to semiconductor integrated circuits, and more particularly to methods and techniques for bonding of passive components with integrated circuits for improved performance and operation.

### BACKGROUND

Many electronic products, particularly mobile computing and/or communication products and components (e.g., notebook computers, ultra-book computers, tablet devices, LCD and LED displays), require multiple DC (direct current) voltage levels. For example, radio frequency transmitter power amplifiers may require relatively high voltages (e.g., 12V or more), and control circuitry may require a low voltage level (e.g., 1-2V). Some other circuitries may require an intermediate voltage level (e.g., 5-10V). Power converters are often used to generate a lower or higher voltage from a common power source, such as a battery, to meet the power requirements of different components in the electronic products. Various configurations of switched capacitor power conversion circuits, sometimes also known as “charge pumps,” provide voltage conversion (i.e., step up, step down, or bidirectional) between a high side voltage and a low side voltage through controlled transfers of charge between capacitors in the circuit.

### SUMMARY

Embodiments consistent with present disclosure provide methods and packages for charge pump modules. According to some embodiments, a method for fabricating a module with reduced area is provided, the method may comprise forming a resin-based substrate by attaching a plurality of multilayer ceramic capacitors (MLCCs) to a base sheet, molding resin around the base sheet and performing one of: removing the base sheet and adding a redistribution layer (RDL) at surfaces of the plurality of MLCCs from which the base sheet is removed, or grinding the molded resin to surfaces of the plurality of MLCCs opposite to surfaces of the plurality of MLCCs facing the base sheet, forming the RDL in an insulating layer on the resin-based substrate and coupling an integrated circuit (IC) to the resin-based substrate.

In another embodiment, a method for fabricating a module with reduced area is provided, the method may comprise forming a resin-based substrate by forming a resin on a plurality of multilayer ceramic capacitors (MLCCs), forming a redistribution layer (RDL) on the resin-based substrate by depositing an insulating layer on the resin-based substrate, forming at least one hole in the insulating layer, and depositing a metal layer on the insulating layer, and coupling an integrated circuit (IC) to the resin-based substrate.

In another embodiment, a method for fabricating a module with reduced area, the method may comprise forming a resin-based substrate by forming a resin on a plurality of multilayer ceramic capacitors (MLCCs), forming a redistribution layer (RDL) in an insulating layer on the resin-based substrate, and coupling an integrated circuit (IC) to the resin-based substrate by forming a plurality of copper pillars on the RDL, building the plurality of copper pillars on the IC, performing face-to-face thermocompression bonding between the resin-based substrate and the IC, forming a pad on the IC and forming a pad on at least one MLCC of the plurality of MLCCs, planarizing the resin-based substrate and the IC, and performing face-to-face hybrid bonding between the resin-based substrate and the IC.

In another embodiment, a package with reduced area is disclosed, the package may comprise a resin-based substrate comprising a plurality of multilayer ceramic capacitors (MLCCs) embedded in a resin, a redistribution layer (RDL) in an insulating layer on the resin-based substrate, and an integrated circuit (IC) coupled to the resin-based substrate.

In yet another embodiment, a method is provided, the method may comprise forming a MLCC-based substrate by forming a resin on a plurality of multilayer ceramic capacitors (MLCCs), wherein each MLCC of the plurality of MLCCs directly contacts another MLCC, forming a redistribution layer (RDL) in an insulating layer on the MLCC-based substrate, and coupling an integrated circuit (IC) to the MLCC-based substrate.

In yet another embodiment, a package is disclosed, the package may comprise a resin-based substrate comprising a plurality of multilayer ceramic capacitors (MLCCs) embedded in a resin, a redistribution layer (RDL) in an insulating layer on the resin-based substrate and an integrated circuit (IC) coupled to the resin-based substrate.

### BRIEF DESCRIPTION OF THE DRAWINGS

FIG. 1 shows an arrangement of electrical components on a printed circuit board making up a charge pump module.

FIG. 2 shows an example of a “resin-based” substrate charge pump module, consistent with embodiments of the present disclosure.

FIG. 3 shows a schematic diagram of key steps to form a resin-based substrate, consistent with embodiments of the present disclosure.

FIGS. 4A-4E show a schematic representation of process steps involved in creation of the resin-based substrate, consistent with embodiments of the present disclosure.

FIGS. 5A-5E show an example of a process involved in creation of the redistribution layer (RDL) for subsequent attachment of a microelectronic chip, consistent with embodiments of the present disclosure.

FIGS. 6A-6D depict an example of a process involved attachment of a microelectronic chip preceded by grinding of resin-based substrate on the side opposite to the base sheet, consistent with embodiments of the present disclosure.

FIG. 7 shows various examples of implementing electrical connections between individual MLCCs making up a resin-based substrate, consistent with embodiments of the present disclosure.

FIG. 8 demonstrates and example of alignment between the substrate and the IC prior to bonding, consistent with embodiments of the present disclosure.

FIG. 9 shows an example of a bonded charge pump module which may be achieved by soldering or thermos-compressive bonding, consistent with embodiments of the present disclosure.

FIG. 10 shows an example of hybrid-bonded interface between the resin-based substrate and the IC, consistent with embodiments of the present disclosure.

FIGS. 11A-11B show configurations of a bonded charge pump module, consistent with embodiments of the present disclosure.

FIG. 12 shows an example of an IC bonded to a resin-based substrate, consistent with embodiments of the present disclosure.

FIG. 13 shows an example of bump formation at the bottom of the resin-based substrate prior to its attachment to the PCB, consistent with embodiments of the present disclosure.

FIG. 14 shows an example of the charge pump module attachment to the PCB, consistent with embodiments of the present disclosure.

FIG. 15 shows an example top and side views of an MLCC sheet as a basis of a substrate for a charge pump module, consistent with embodiments of the present disclosure.

FIG. 16 shows a schematic diagram of key steps in preparation of the MLCC-based substrate for coupling to the IC, consistent with embodiments of the present disclosure.

### DETAILED DESCRIPTION

Charge pump modules offer an inexpensive and simple solution for voltage conversion under low voltage conditions in small battery powered application including mobile phones and personal digital assistants (PDAs). Charge pump solutions often opt for usage of capacitors over inductors due to improved size, cost, reduced electromagnetic interference (EMI) and lower layout sensitivity. Charge pump modules may include an array of capacitors electrically coupled to at least one integrated circuit (IC), whose architecture closely depends on the specific application. Conventional solutions may see monolithic integration of capacitors and the IC(s) resulting in planar distribution of passive and active components. Alternatively, off-the-shelf capacitors and electronic chips containing packaged IC(s) may be integrated onto a printed circuit board (PCB) resulting in chip placement in close proximity to or completely surrounded by the passive components.

One of the main disadvantages of conventional solutions for charge pump modules involves significant area required for placement of all necessary passive and active components. Moreover, several challenges arise from thermal management standpoint. The operating chip may heat up to significant temperatures potentially leading to significant deterioration of electrical performance and efficiency of the module if not managed adequately. In most conventional designs, heat dissipation may primarily take place through metal contacts and into the PCB, which may be characterized by poor thermal conductivity. Solutions aimed at bringing heat sinks into close contact with the chip may also be impeded by proximity of large capacitors, restricting access to hotspots of heat dissipation.

Embodiments of the present disclosure are directed to methods for fabrication of and packages for highly efficient charge pump modules of reduced area to allow for more effective heat management and reduced manufacturing costs.

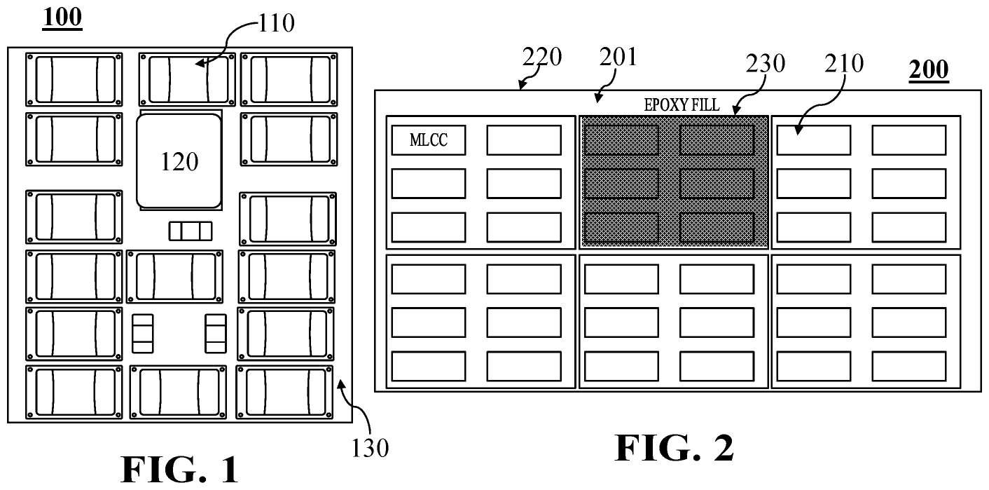

FIG. 1 shows an example of a charge pump module 100, which may include a plurality of capacitors 210 and an integrated circuit (IC) or a microchip (chip) 230 (for simplicity, from here on terms IC and chip/microchip will be used interchangeably) that may be arranged and integrated within a printed circuit board (PCB) 130. A typical PCB may consist of flat sheets of conductive material, commonly copper (Cu), laminated onto and/or placed in between sheets of insulating substrate. Copper may be shaped via an appropriate process to form conductive lines, also known as tracks or circuit traces to provide electrical connection between various passive and/or active electrical components that may be arranged on the surface of the PCB and connected to the tracts via soldering or any other suitable method. Alternatively, placement of electrical components on the PCB may also involve cutting out sections of the PCB of appropriate size and depth followed by placement on the components in the troughs thus created. Such component may be connected to other components integrated onto the PCB via Cu tracks.

A typical IC may contain large numbers of electrical components of different types depending on intended application, including transistors, resistors, diodes, capacitators, inductors etc. Generally, the operation of a microchip may predominantly rely on utilization of active electronic components. Active components may be defined as electronic components supplying energy to an electronic circuit and may be controlling current flows. Examples may include transistors, diodes and thyristors. In contrast, passive component may receive, dissipate and/or store energy by maintaining electric and/or magnetic fields. Passive components may include capacitors, inductors, and resistors.

As shown in FIG. 1, the chip 120 may be placed relatively centrally on the PCB or in any other planar configuration that supports electrical connections between the capacitors 110 and the chip 120. Performance of the chip 120 may primarily rely on the functionality of active components and due to inherent energy losses during their operation, chip 120 may dissipate significantly more heat than the surrounding capacitors 110. In case of planar arrangement of the components 110 and 120 as shown in FIG. 1, the primary path for heat dissipation may involve electrical connections of the chip 120 and into the PCB 130. As a result of poor thermal conductivity of the PCB 130, heat diffusion away from the chip may be significantly reduced and may impact the efficiency of the entire module.

FIG. 2 shows an example of a charge pump module 200, consistent with embodiments of the present disclosure. The following examples are discussed using multilayer ceramic capacitors (MLCCs), however a person skilled in the art would recognize that in some embodiments MLCCs may be exchanged for any other suitable capacitor, for example any other ceramic capacitor, tantalum capacitors, aluminum capacitors etc. According to one embodiment of the present disclosure, MLCC capacitors 210 may be arranged and encapsulated in an epoxy resin 201 to form a “resin-based” substrate 220. It is important to note that epoxy resin is only an example of a resin that may be used to form such substrate. Other resins may be used to encapsulate the passive components depending on the intended application of the module 200.

Referring to FIG. 2, upon formation of the resin-based substrate, at least one chip 230 may be placed on top of such substrate and connected to at least one capacitor 210 to form a charge pump module 200 of reduced surface area. The arrangement shown in FIG. 2 presents multiple advantages in performance and cost over the approach shown in FIG. 1. Firstly, despite comparable surface area, module 200 may accommodate multiple chips 230 in comparison to one chip of the module 100, leading to increased power density of the module and cost reduction associated with raw materials required. Additionally, placement of the chip 230 on top of capacitors allows for easy access to the chip 230, which may therefore be bonded or otherwise brought into contact with a heat sink for improved thermal management. Moreover, the chip may be ground down to a required thickness without reducing structural and/or mechanical stability of the module.

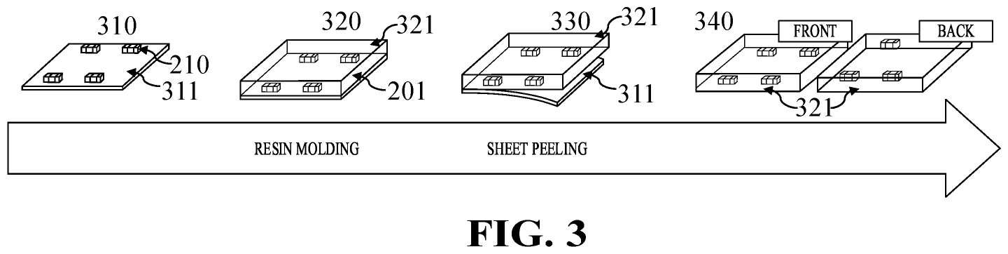

In some embodiments of the present disclosure, a method for fabrication of module with reduced surface area may include forming a resin-based substrate by attaching a plurality of multilayer ceramic capacitors (MLCCs) to a base sheet and molding resin around the base sheet. FIG. 3 shows a schematic diagram outlining key steps in formation of the resin-based substrate, consistent with embodiments of the present disclosure. Initially, MLCC capacitors 210 are arranged on the base sheet 311 as shown in step 310, followed by a process for encapsulation of capacitors 210 in resin mold 321, for example resin molding or any other suitable process, as shown in step 320. As a result, capacitors 210 are still arranged on top of the base sheet 311 while also enclosed in a solid resin mold 321. The following step 330 involves removal of the base sheet 311 to leave a solid resin casing that may be semitransparent as shown in step 340.

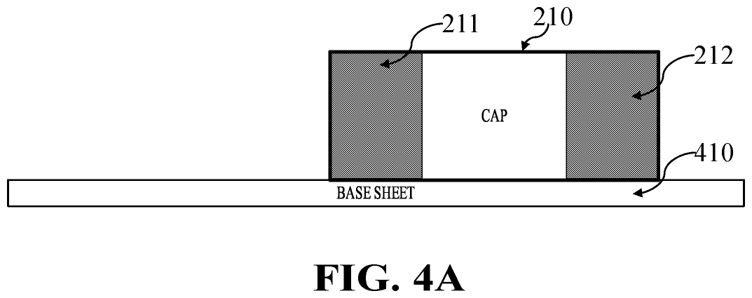

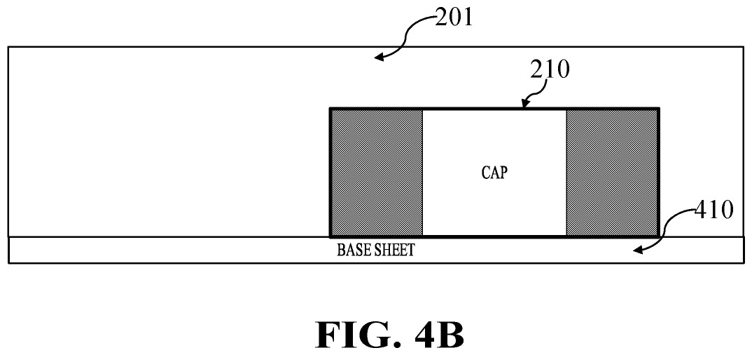

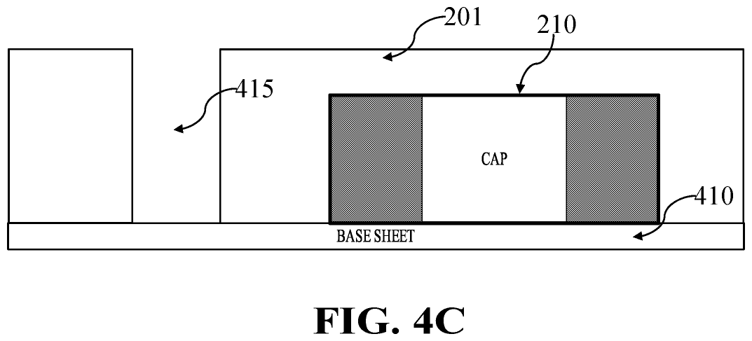

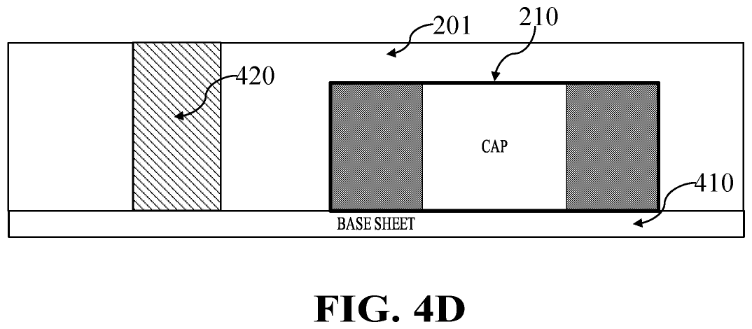

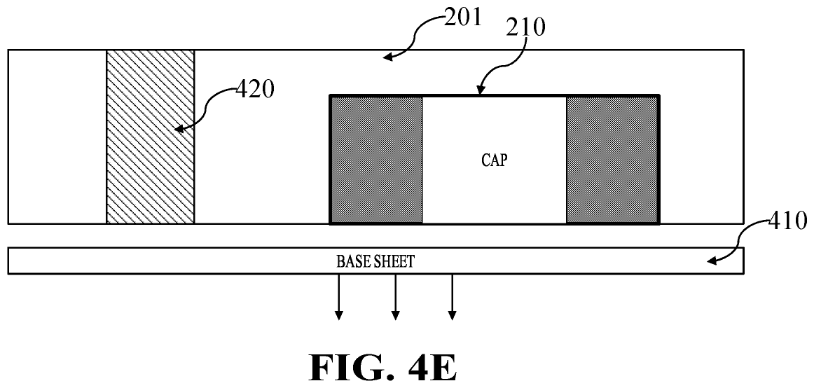

FIGS. 4A-4E show a schematic representation of the process steps involved in creation of the resin-based substrate, consistent with embodiments of the present disclosure.

FIG. 4A shows the first step in formation of the resin-based substrate 220, which may involve attachment of the MLCC capacitors 210 to the base sheet 410. It is noteworthy, that capacitor 210 may comprise two metallic electrodes 211 and 212, which may provide electrical connections for applying bias to the capacitor. Throughout the description it may be assumed that each capacitor is equipped with such metallic electrodes, however for simplicity and clarity purposes these electrodes may be omitted in further figures and discussion.

The base sheet may be made of a polymer or may comprise a metal sheet that may be covered with polymer. Adhesive properties of the base sheet may be sufficient for MLCC capacitors 210 adhere to the base sheet 410 comprising a polymer with an adhesive property. As shown in FIG. 4B, the subsequent step in fabrication of the resin-based substrate may involve deposition of the resin mold 201 around the capacitors 210 and any other components attached to the base sheet 410. In some embodiments, the resin used in the method for fabrication of module with reduced surface area may comprise an epoxy.

To provide an electrical connection across the substrate, resin mold may be locally removed as indicated by the hollowed area 415 in FIG. 4C. Subsequently, a copper pillar 420 may be formed on the base sheet 410, which at later stages may form a through via across the substrate (see FIG. 4D). Finally, as shown in FIG. 4E, in some embodiments the base sheet may be removed followed by addition of a redistribution layer (RDL) at surfaces of the plurality of MLCCs from which the base sheet is removed. The base sheet removal may be achieved by mechanical means, where a medium such as gas or change in temperature or light may be employed to reduce adhesive energy of the interface between the base sheet and the resin-based substrate prior to its mechanical removal.

Formation of the RDL may comprise depositing the insulating layer on the resin-based substrate, forming at least one hole in the insulating layer, and depositing a metal layer on the insulating layer. Deposition of the insulating layer, which may also be referred to as passivation, may involve any of the typical fabrication techniques used in the art such as sputtering, spin-coating, electrochemical deposition, any of the chemical-vapor deposition (CVD) techniques or any other method common in semiconductor front-end and back-end manufacturing process. Formation of holes, gaps, vias or other channels in the passivation may be achieved by means physical or chemical etching, whereby sections of the material are exposed to chemical or physical agents resulting in removal of these sections of the material. Once the exposed sections (or “holes”) are created, the metal may be deposited by, for example a sputtering process. Further etching may be applied to the metal surfaces to achieve desired shapes and profiles.

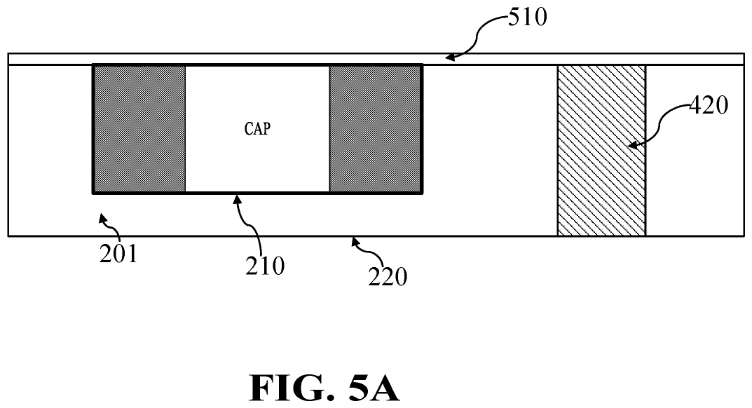

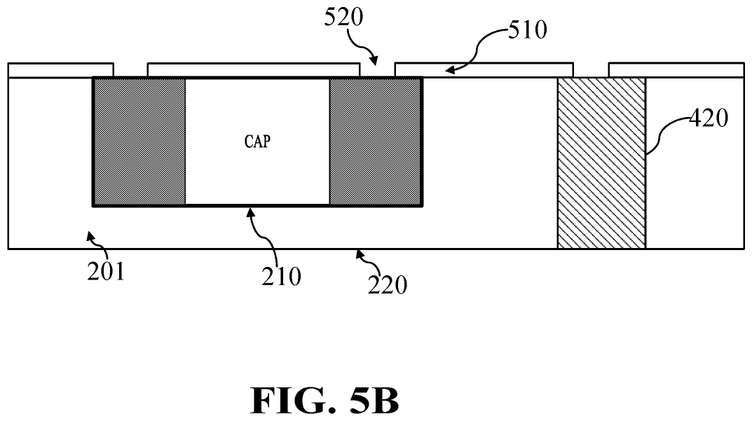

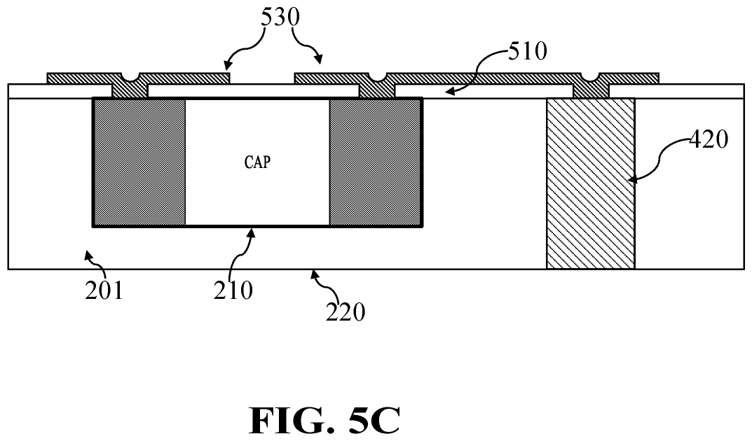

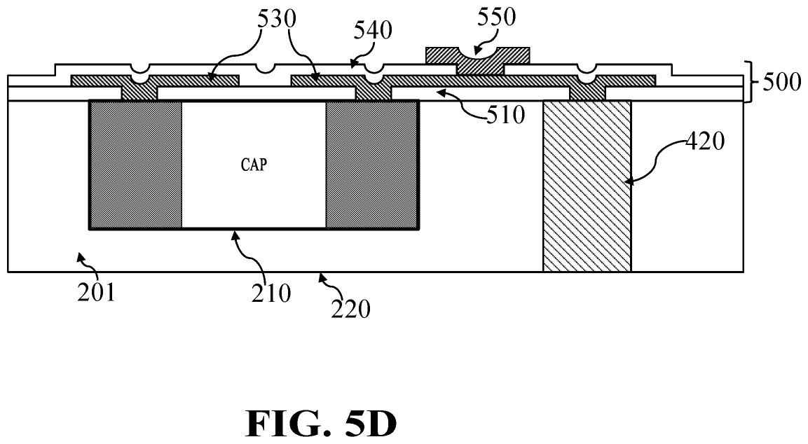

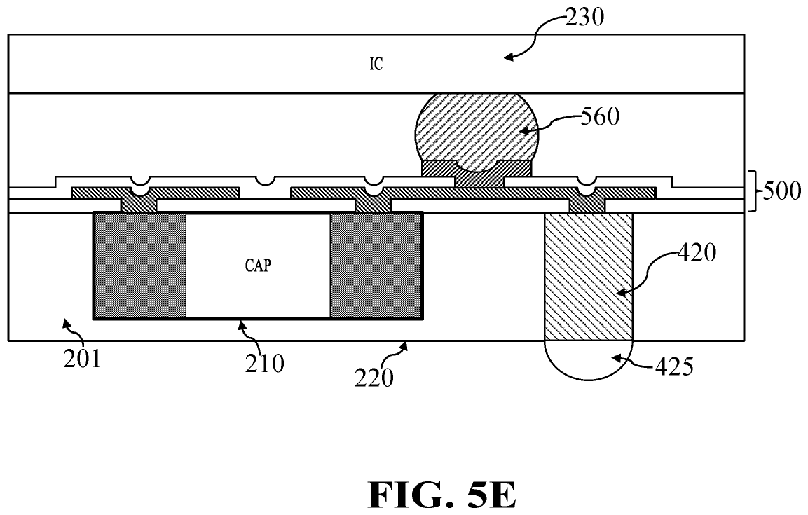

An Example of a redistribution layer 500 connecting resin based substrate 220 to IC 230 is shown in FIG. 5E. The RDL may serve as the connection point between the chip 230 and at least one capacitor. The metal layers of the RDL may be directly responsible for providing electrical connection between selected terminals of the capacitor 210 and the chip. Typical metals used for fabrication of these connections may involve copper and may be deposited by typical fabrication means such as sputtering, electroplating or other suitable methods.

The metal connections of the RDL may by passivated by means of an insulator. In some embodiments, the insulating layer may comprise a polyimide or an oxide. The passivation of the RDL may comprise forming at least one pad on the RDL, which may serve to provide electrical connection to predetermined passivated terminals or components. In some embodiments, the RDL may comprise plurality of passivation layers. For example, the RDL may comprise a first passivation layer and the at least one pad may be located on the first passivation layer. Additionally, the RDL may comprise a second passivation layer and the at least one pad may be located between the first passivation layer and the second passivation layer.

FIGS. 5A-5E depict an example of a process in which RDL is created to facilitate substrate coupling to an IC, consistent with embodiments of the present disclosure. As shown in FIG. 5A, resin-based substrate 220 may comprise at least one MLCC 210 and a Cu pillar 420 bound by resin mold 201. The first step may involve deposition of the first passivation layer 510 on the side of the substrate 220 from which the base sheet was removed. As shown in FIG. 5B, passivation layer 510 may be etched away to create exposed areas (holes) 520 over electrical terminals in preparation for deposition of metal connections to the capacitors 210 or any other components comprised in the resin-based substrate 220. As shown in FIG. 5C, metal contacts 530 may be deposited to create pads for electrical connections. For example, a connection between one terminal of the capacitor 210 and the Cu pillar 420 may be created in this way. In subsequent steps, as shown in FIG. 5D, further passivation 540 may be deposited to protect exposed electrical connections. This layer may be etched to deposit a single small pad 550 that may provide access to one terminal of the capacitor 210 and the Cu pillar 420. As shown in FIG. 5E, the RDL 500 may provide an electrical connection between the passive component of the substrate 220 and the IC 230. As demonstrated in FIG. 5E, the substrate may be coupled to the chip via a solder bump 560. However, other coupling methods are also possible and discussed in more detail in further sections. The substrate 220 is further finished by attaching or applying a solder cap 425 to copper pillar 420, so that substrate 220 can be attached to an external circuit such as a PCB.

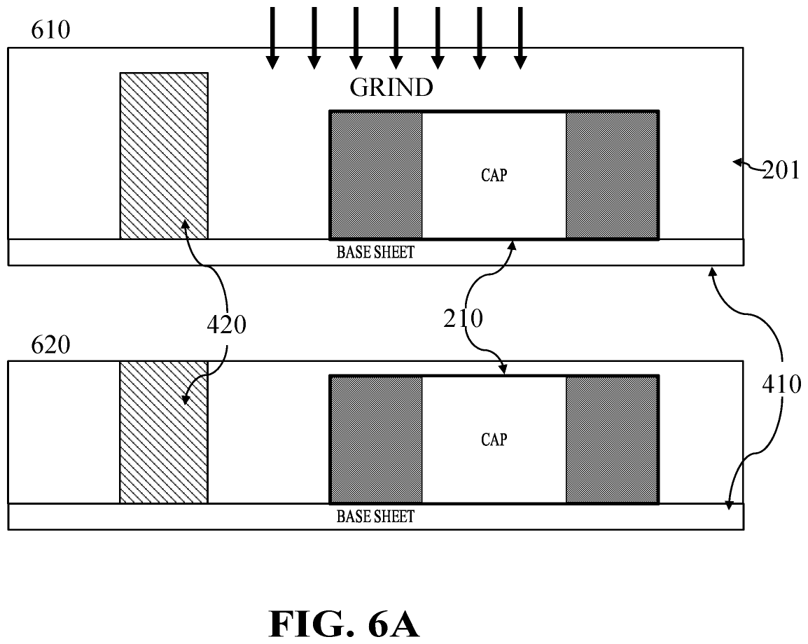

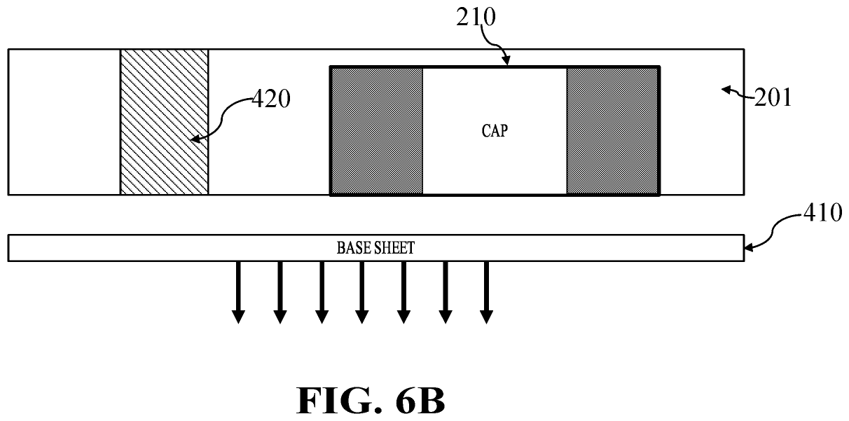

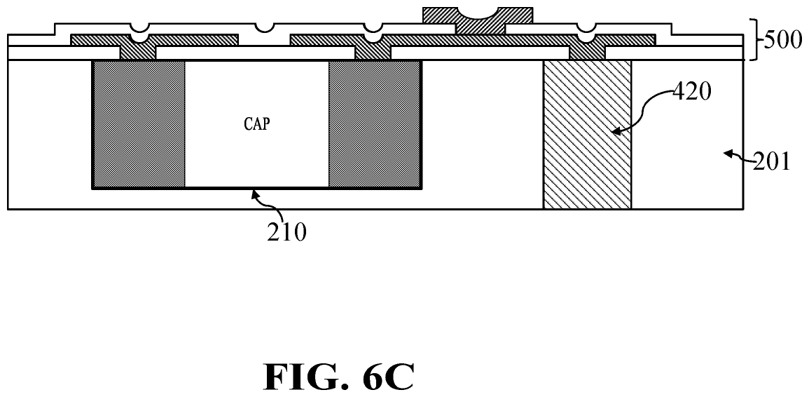

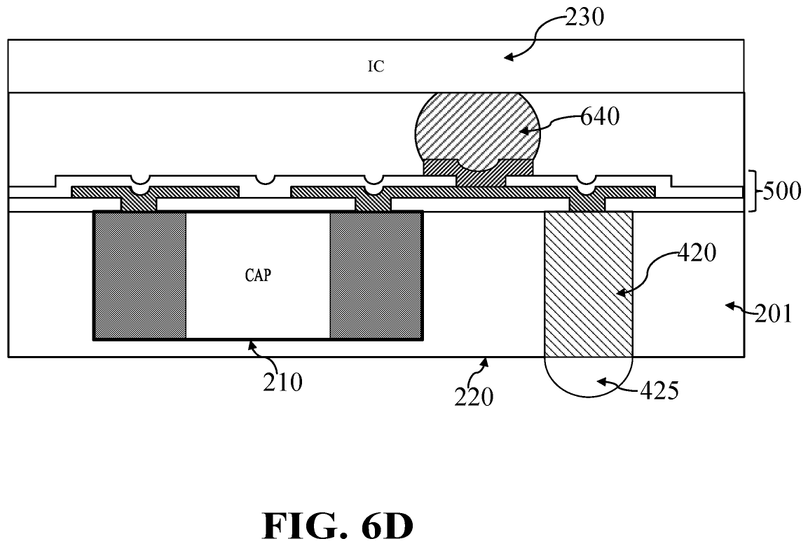

Alternatively, following encapsulation of the base sheet and the capacitors by the resin mold, the next step of the process may involve grinding the molded resin to surfaces of the plurality of MLCCs opposite to surfaces of the plurality of MLCCs facing the base sheet and forming the RDL in an insulating layer of the resin-based substrate. FIGS. 6A-6D depict an example of a process involving attachment of a microelectronic chip preceded by grinding of resin-based substrate on the side opposite to the base sheet, consistent with embodiments of the present disclosure.

As shown in FIG. 6A, the substrate 610 may be ground on the side opposite to the base sheet 410 to reduce its thickness such that the thickness of grinded substrate 620 is comparable to the thickness of individual constituent capacitors 210. The grinding may be performed using standard grinding techniques, for example using a back-grinding equipment that may be equipped with a spinning abrasive wheel. Grinding may result in significant reduction in substrate thickness allowing for more effective heat dissipation and improved thermal performance of the substrate.

In the subsequent step, depicted in FIG. 6B, base sheet 410 may be removed in preparation for deposition of the RDL. Base sheet 410 may be removed mechanically as described above. The RDL 500 may be deposited over the exposed surface following removal of the base sheet (see FIG. 6C) by applying the process steps described above, which may involve sequential deposition of passivation and metal layers combined with selective etching to create electrical connections to appropriate electrical terminals. As shown in FIG. 6D, resin-based substrate 220 prepared in such manner may enable coupling of an IC 230 to the substrate 220 via a solder bump or 640 or any other suitable coupling method. The substrate 220 is further finished by attaching or applying a solder cap 425 to copper pillar 420, so that substrate 220 can be attached to an external circuit such as a PCB.

Although the methods described above refer to formation of the RDL on the site previously occupied by the base sheet, in some embodiments the RDL may be formed on the side opposite to the base sheet. Following the grinding step shown in FIG. 6A, the layer of remaining resin mold covering the capacitor may be locally chemically etched to expose capacitor's electrodes. Following base sheet removal, the deposition of the RDL may follow standard process described above.

In some embodiments, at least two MLCCs of the plurality of MLCCs making up the resin-based substrate may be electrically coupled to each other. Providing an electrical coupling of at least two capacitors may allow for obtaining an effective combined capacitance not possible with a single capacitor. Another advantage of selecting a plurality of discreet capacitors for the formation of the resin-based substrate may involve selection of individual capacitors depending on the intended application. For example, one of the MLCCs may have a voltage rating that may be different from that of another of the MLCCs.

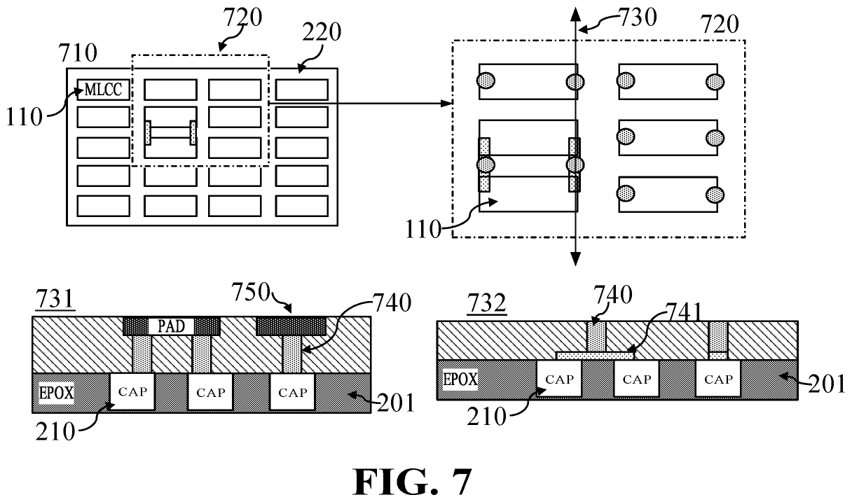

FIG. 7 shows various examples of implementing electrical connections between individual MLCCs making up a resin-based substrate, consistent with embodiments of the present disclosure. Regardless of voltage ratings and capacitances of individual capacitors making up the substrate, at least two MLCCs may be electrically coupled, as demonstrated in FIG. 7. Panel 710 shows a resin-based substrate 220 comprising MLCCs 210 molded in epoxy resin. Section 720 of the substrate shows an example of an electrical connection formed between two capacitors, which may be realized in at least two different ways. Cutline 730 shows two such metallization structures in the form of side view diagrams 731 (for thermocompression bonding) and 732 (for hybrid bonding). In some embodiments, each of the at least two capacitors 210 may be contacted first by a Cu plug 740 followed by deposition of a metal pad 750, as demonstrated in cutline 731. Alternatively (see cutline 732), two MLCCs may first be connected by metallization 741 and a single Cu plug 740 may be deposited over the top. The choice of electrical connection may be affected by the intended method for coupling of the substrate with an IC.

Additionally, in some embodiments the process of forming appropriate electrical connections in preparation of bonding may comprise forming at least one via to extend through the resin. Depending on the intended application of the module, it may be advantageous to introduce such electrical connections across the substrate that may allow for direct connection to the IC positioned on the opposite side. Likewise, for other applications, it may be advantageous to create a connection across the chip directly to the resin-based substrate. In such cases, the method may also comprise forming at least one via to extend through the IC.

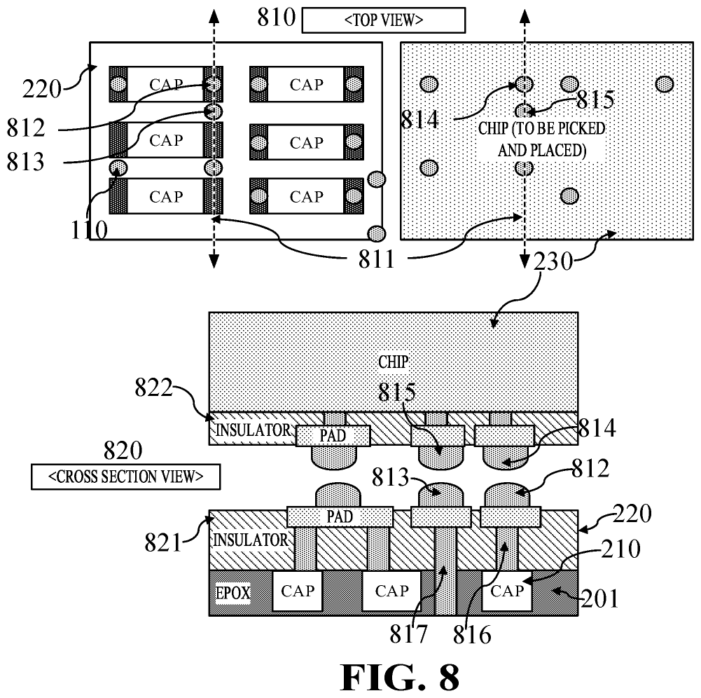

Attachment of the resin-based substrate 220 to the chip 230 may require prior alignment of both elements, as outlined in FIG. 8, consistent with embodiments of the present disclosure. Please note, for simplicity and the terminals of the MLCCs are not always shown in the figures. Top view 810 of the resin-based substrate 220 and the chip 230 to accentuate the location of pads and pillars that may be involved in coupling of the two elements. Individual capacitors 110 constituent of the substrate are contacted by pads providing electrical connections to the individual MLCCs, as demonstrated by pillars or studs 812 and 813. Each pillar may be coupled to an electrical component via a copper plug. For example, pillar 812 and the corresponding pad may be couple to the MLCC 210 via the plug 816. Alternatively, pillars may be connected to plugs that may serve as through vias, see for instance pillar 813 and its corresponding plug 817.

The pillars of the resin-based substrate may have corresponding pillars or studs on the chip as shown along the cutline 811. For instance, as shown in FIG. 8 pillars 812 and 813 of the resin-based substrate may correspond to pillars 814 and 815 of the IC. In order to couple the substrate 220 and the chip 230, both elements may require alignment such that pillars on one structure are positioned to form direct contact with corresponding pillars on the other structure, as shown in cross-section view 820. In the present example, pillar 812 of the substrate may be placed directly below corresponding pillar 814 on the IC. Likewise, pillar or studs 813 may be positioned underneath the corresponding pillar 815 of the IC. Once all the pillars may be aligned with their respective counterparts, the coupling of the substrate and the IC may take place.

It is worth noting, that similar approach may be adopted when boding via soldering bumps. In such embodiments, rather than performing thermos-compressive bonding of the corresponding pillars of the resin-based substrate 220 and the IC 230, the substrate and the IC may be aligned and joined by soldering as described with reference to FIGS. 5E and 6D.

Following the alignment of the chip and the substrate, the resin-based substrate may be ready for its bonding to the chip or IC, such that the IC may be electrically coupled to at least one MLCC of the plurality of MLCCs. In some embodiments, the IC may be coupled to the resin-based substrate by at least one solder bump or copper pillar on the at least one bump or pillar. To provide greater structural stability and mechanical strength, the interface between the resin-based substrate and the IC may be encapsulated in a suitable mold compound. The added stability may allow for further processing of the bonded chip mitigating the risk of mechanical failure of the bonded interface (e.g., due to thermal cycling, grinding or any other necessary processing step).

For some applications, soldering the IC to the resin-based substrate may not constitute the most appropriate method for coupling of the two, as soldering may result in significant thickness of the bond interface, which in some cases may exceed 80 μm. For applications with restrictions on vertical dimensions of the module, such added thickness may render the method inappropriate.

Alternatively, coupling the IC to the resin-based substrate may comprise thermo-compression bonding. This method may involve alignment of corresponding pillars on the resin-based substrate and the chip as described above. Subsequently, the bonding may involve application of compressive force bringing the two units together at elevated temperatures. Depending on metals present in the pillars, the temperatures required for bonding may exceed 300° C. The resultant interfacial thickness may be on the order of 30-40 μm, offering significant improvement in comparison with soldering. Thermo-compressive bonding may therefore be more suitable for applications requiring some restraint on the stack height of the charge pump module.

Upon successful bonding of the chip to the substrate by means of soldering or thermocompression, there may exist an air gap between in the recess areas located in between bonded bumps. In order to strengthen the newly formed interface, the next step of the process may comprise forming an underfill between the IC and the resin-based substrate. The process of forming the underfilling may involve introduction of a low-viscosity adhesive to fill the voids in between the bonded bumps. Elevated temperature may be applied to reduce the viscosity of such adhesive and provide additional support for the interface, in anticipation of applied thermo-mechanical stress in the following processing steps, for example grinding, polishing or any other step performed on the bonded module or during operation.

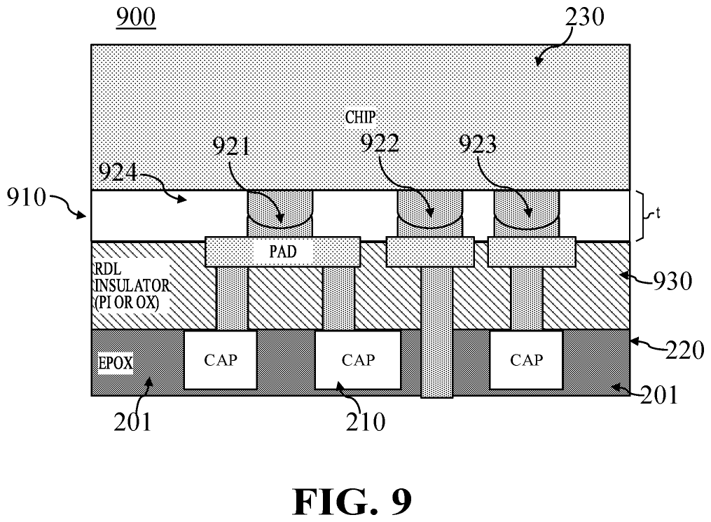

FIG. 9 shows an example of a bonded charge pump module 900 coupled by means of soldering or thermos-compressive bonding, consistent with embodiments of the present disclosure. Module 900 includes the resin-based substrate 220 coupled to the IC 230 via the bond interface 910 of the thickness t. The interfacial thickness t may vary depending on the bonding methods as described above, with soldering characterized by greater values of t in comparison to thermo-compressive bonding. The substrate and the IC may be coupled via aligned pillars, which may be brought together to form electrical connections between the two units as shown by bonded pillars 921, 922, and 923. The void areas in between the pillars 921, 922, and 923 may be filled with underfill 924 for added mechanical strength in anticipation of thermo-mechanical strain exerted on the newly formed interface during further processing of the module.

Although thermo-compressive bonding shows significant reduction in the thickness of the bonded interface t in comparison to soldering, there may exist applications where such reduction in stack height may still be insufficient. In some embodiments, coupling of the IC to the resin-based substrate may comprise hybrid bonding. The method utilizing this type of bonding may include forming an oxide layer prior to coupling the IC to the resin-based substrate. Deposition of thin oxide layer on both target bond interfaces may constitute an important step of the process due to high bond strength between direct oxide-to-oxide bonded interfaces. The oxide may be deposited by sputtering, chemical vapor deposition (CVD) or any other suitable technique depending on the process requirements.

Similar to bonding techniques described above, hybrid bonding also requires alignment of corresponding pillars of the chip and the substrate, such that hybrid bonding may take place between at least one pillar of the IC and at least one pillar embedded in the insulating layer. Prior to alignment of the substrate and the chip, the surfaces may require planarization, which may result in bringing the surface roughness below root mean square value of 5 Å. In some embodiments, the planarization may be achieved by performing chemical mechanical planarization (CMP) prior to coupling the IC to the resin-based substrate. CMP process may be performed by a variety of abrasive and corrosive chemical slurries, for example alkaline slurries in combination with an abrasive tool.

Upon bringing the surfaces of the substrate and the chip together, due to high degree of smoothness of both interfaces van der Waals bonding may form between the two surfaces. Subsequently, the bonded module may undergo thermal annealing at relatively low temperatures, typically not exceeding 200° C. At such elevated temperatures, a strong bond may form between oxide layers deposited at interfaces. Additionally, copper making up the electrical connections of the IC and the substrate may diffuse across the oxide interface providing additional bonding points along the interface. Therefore, hybrid bonding may be referred to as thus due to dual nature of bonded interface relying on oxide-to-oxide adhesive bonding and copper diffusion taking pace between aligned electrical connections.

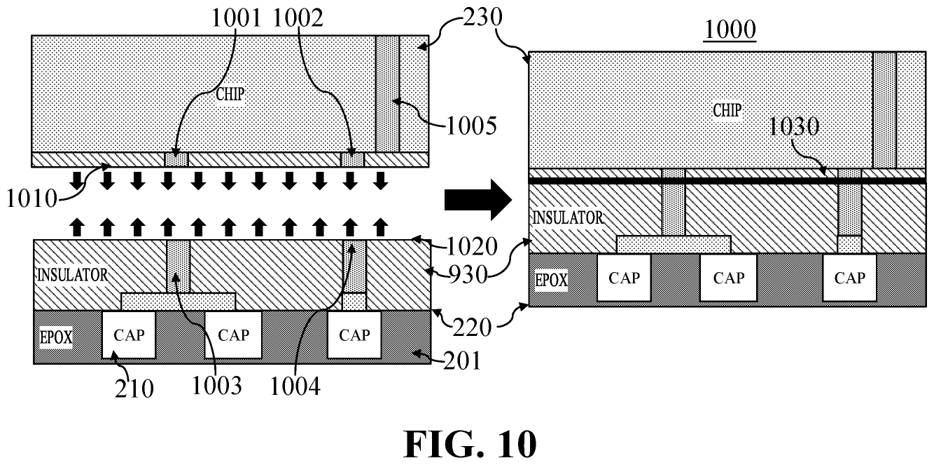

FIG. 10 shows an example of hybrid bonding between the chip 230 and the substrate 220 to form a charge pump module 1000, consistent with embodiments of the present disclosure. In this example, the metal contacts 1001-1004 on the chip 230 and the substrate 220 are covered in an oxide, which may subsequently be planarized by CMP to achieve desired surface roughness as described above. This may result in formation of smooth interface 1010 on top of the IC 230 and a smooth interface 1020 on top of the resin-based substrate. Both interfaces may be brought into contact such that pairs of corresponding plugs (1001 and 1003, 1002 and 1004) may be aligned upon bonding. Following the hybrid bonding process as described above, the module 1000 may comprise a very thin interface 1030. For this bonding technique, the resultant interface 1030 may have thickness on the order of 1 μm, offering significant improvement in stack height in comparison to both soldering and thermo-compressive bonding. Although in the present example through via 1005 is not bonded to a corresponding plug on the chip 230, in some embodiments via 1005 may take part in the bonding process by undergoing identical process as described with reference to plugs 1001-1004.

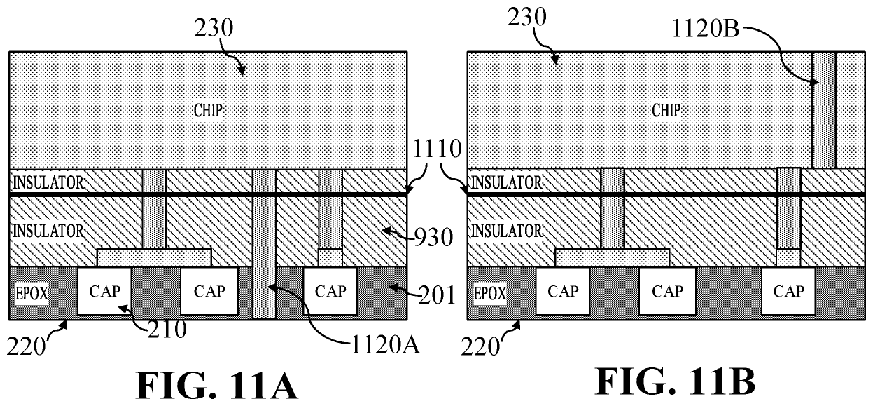

FIGS. 11A and 11B show two further examples of charge pump modules coupled by hybrid bonding method along the bond interface 1110, consistent with embodiments of the present disclosure. As demonstrated in FIGS. 11A and 11B, depending on the intended application, the through via 1120A may be fabricated across the resin-based substrate 220 (FIG. 11A) providing direct electrical connection to the chip 230. Alternatively, a through via 1120B may be fabricated across the chip 230 as demonstrated in FIG. 11B.

In some embodiments, the coupling of the IC to the resin-based substrate may comprise forming a plurality of copper pillars on the RDL, building the plurality of copper pillars on the IC and performing face-to-face thermocompression bonding between the resin-based substrate and the IC. Alternatively, the coupling of the IC to the resin substrate may involve forming a pillar on the IC and forming a pillar on at least one MLCC of the plurality of MLCCs, planarizing the resin-based substrate and the IC; and performing face-to-face hybrid bonding between the resin-based substrate and the IC.

In some embodiments of the present disclosure, the method for formation of a module with reduced area may include grinding the IC to 50 μm. Depending on the intended application, the module may be presented with height constraints requiring reduction in vertical dimension of the stack. In order to comply with the required size, the IC may be ground down to 50 μm by means of conventional methods and techniques know to one skilled in the art, for example wafer back-grinding.

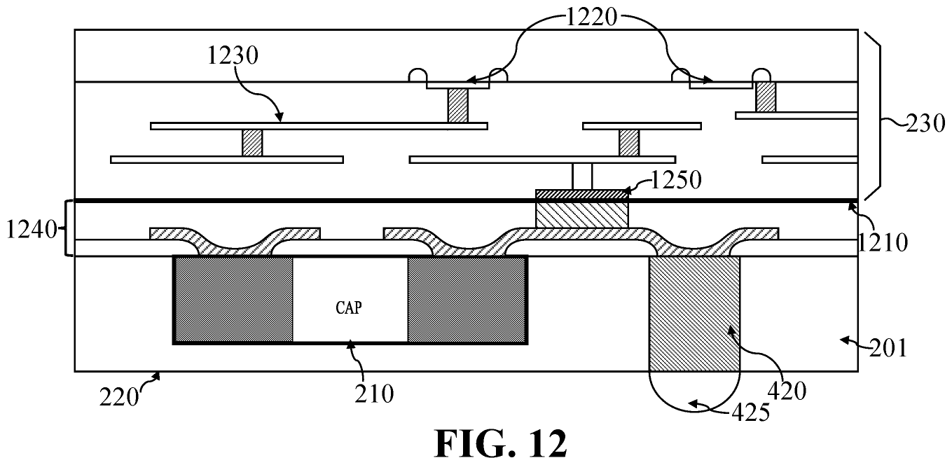

FIG. 12 shows an example of a charge pump module coupled by hybrid bonding along the interface 1220, consistent with embodiments of the present disclosure. In this example, resin-based substrate 220 is joined with an integrated circuit 230 including plurality of field effect transistors (FETs) 1220 interconnected to other active and/or passive components of the IC via metallization layers 1230 characteristic of a typical Si front-end fabrication process. The section of the module shown in the present example includes RDL 1240 comprising a single pad 1250 via which the electrical connection to the IC is formed. However, in some embodiments, the IC 230 may contain a plurality of FETs and diodes that may require multiple connections to the substrate 230. The substrate 220 is further finished by attaching or applying a solder cap 425 to copper pillar 420, so that substrate 220 can be attached to an external circuit such as a PCB.

In some embodiments, grinding may also be employed as an indirect measure for improved thermal management of the module. By reducing its thickness, the IC may be configured to transfer heat directly to a heat sink. The active components of the integrated circuit may dissipate significant amounts of heat resulting from electrical losses of the circuit. Through reducing the thickness of the IC, the thermal resistance of the IC in the vertical direction may be significantly reduced. Moreover, a heat sink of choice may be brought into contact with the ground down IC, such that the heat sink may be placed in close proximity of the hotspots, thus facilitating more effective heat conduction away from the IC of reduced thickness. Examples of heat sinks may include passive heat sinks, where the choice of materials and designs may dictate their cooling capabilities, and active heat sinks where fluid flows may be utilized for heat extraction.

In some embodiments, the module may require electrical connections to external electrical components and, therefore, additional electrical connections may be implemented. Integration with other electrical components may be realized by placing the module on a typical PCB and providing appropriate electrical connections to metal tracks of the PCB. In some embodiments, the connection may be required from the substrate side, and its formation may comprise forming a bump on a side of the resin-based substrate that is opposite to a side of the RDL and coupling the resin-based substrate to a printed circuit board (PCB) by the bump. In this way, an electrical connection may be formed directly below the module at the interface opposite of the IC.

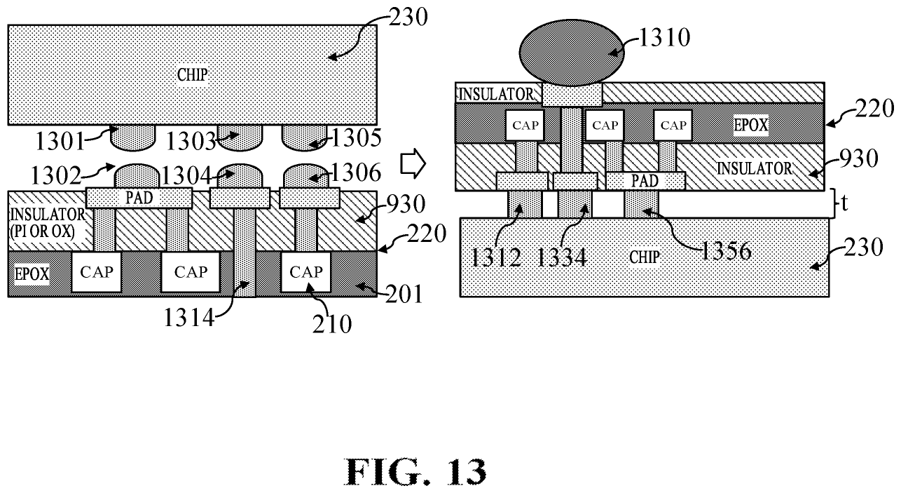

FIG. 13 shows an example of a bonded module where the chip 230 and the resin-based substrate 220 may be coupled by soldering or thermo-compressive bonding, such that corresponding pairs of pillars 1301 and 1302, 1303 and 1304, 1305 and 1306 form electrical connection points between the substrate and the chip, consistent with embodiments of the present disclosure. Through via 1314 extending across the substrate 220 and connected to pillar 1304 serves as an electrical connection to the chip 230 by its bonding to pillar 1303. Depending on the coupling method, the bonding interface may have a thickness t, which may be predominantly dictated by the thickness of the electrical connections 1312, 1334, and 1356. Following bonding, the chip 230 may be ground down to required thickness. Cu solder bump 1310 may be fabricated at the bottom of the resin-based substrate in anticipation of module coupling to the PCB.

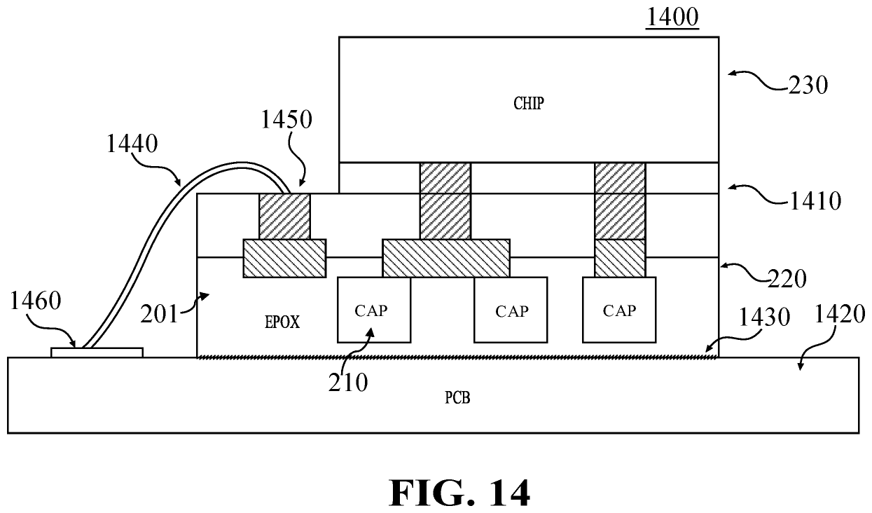

Alternatively or additionally, a wire bond connection between the substrate and the PCB may be preferred for some applications. FIG. 14 shows an example of one such embodiment, where the chip 230 may be bonded to the resin-based substrate 220 by hybrid bond 1410, consistent with embodiments of the present disclosure. The module 1400 may be attached to the PCB 1420 by an adhesive along the interface 1430. Examples of adhesives that may be used for attaching the module to the PCB 1420 may include an epoxy. The electrical connection between the module and the PCB 1420 may comprise coupling the resin-based substrate to a printed circuit board by a wire. As shown in FIG. 14, the wire bond 1440 may extend between the electrode 1450 of the resin-based substrate and the metal contact 1460 of the PCB 1420. Such electrical connection may allow for integration of the module with other electrical components present on the PCB 1420.

The processing steps described above may be utilized to manufacture a package that may comprise a resin-based substrate comprising a plurality of MLCCs embedded in a resin, a redistribution layer in an insulating layer on the resin-based substrate and an IC coupled to the resin-based substrate. The formation of a package charge pump module may follow any of the embodiments previously described. Upon successful bonding of the IC to the resin-based substrate, the module may be packaged using any suitable method. The package may facilitate electrical connections between the module and the external circuitry and may include component for improved thermal management.

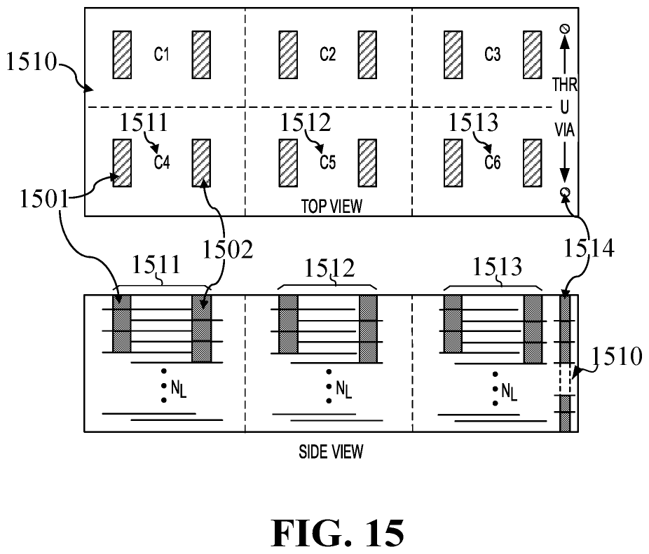

In some embodiments of the present disclosure, an alternative method for formation of the substrate based on MLCCs may be employed. In this method, rather than arranging discrete MLCCs and molding an epoxy around them, a sheet of MLCCs may be used. FIG. 15 demonstrates an example of such an undivided sheet of MLCCs 1510 as a basis of a substrate for a charge pump module, including multiple individual capacitors 1511, 1512, and 1513 and a through via 1514 for electrical connection to the surrounding circuitry, consistent with embodiments of the present disclosure. Each of the MLCCs may be made up of a plurality of intermittent metal and ceramic layers, whose number Nz may determine the voltage rating of the capacitors. For this reason, the plurality of MLCCs making up the substrate may have a same voltage rating. In addition, each MLCC may be equipped with a pair of metallic electrodes, such as metallic electrodes 1501 and 1502 of the capacitor 1511. These metallic provide electrical connection for applying bias of desired polarity to the capacitor.

Depending on the intended application of the module, the capacitance values required by the system may differ from capacitances of individual capacitors comprising the substrate. Therefore, in some embodiments at least two MLCCs of the plurality of MLCCs may be electrically coupled to each other to achieve intermediate capacitance values according to configuration in which said capacitors may be coupled.

In one such embodiment, the method for making a module of reduced area may include forming a MLCC-based substrate by forming a resin on a plurality of multilayer ceramic capacitors (MLCCs), wherein each MLCC of the plurality of MLCCs may directly contact another MLCC. The resin may include an epoxy and it may be deposited over the sheet of MLCCs.

Subsequent steps of the method may include forming a redistribution layer (RDL) in an insulating layer on the MLCC-based substrate. For the purposes of the RDL, the insulating layer may include a polyimide or an oxide, which may be deposited as described above. Similar to embodiments employing a resin-based substrate, the RDL may serve as an intermediate layer facilitating electrical contacts between the substrate and the chip. Thus, fabrication of connections and passivation may be required, such that the method herby disclosed may include forming at least one pad on the RDL.

To provide appropriate protection and separation of electrical connections, the RDL may include a first passivation layer and the at least one pad is on the first passivation layer. The passivation layer may be deposited by sputtering, CVD or any other suitable method following etching and metal sputtering to create conductive connections and pads to relevant terminals of the MLCCs forming the substrate. Additionally, the RDL may include a second passivation layer and the at least one pad is between the first passivation layer and the second passivation layer. A pad located at the top of the first passivation may provide an electrical connection to selected parts of the substrate for any external components such as the IC to be bonded. Introduction of additional layer of metallization may therefore require additional protection in the form of a second passivation layer.

Prior to bonding, the process of manufacturing a module of reduced surface area may further include cutting the MLCC-based substrate. The substrate may be diced in a manner that may be most suitable for the intended IC from the perspective of area and capacitance requirements. Dicing may follow the boundaries created by individual capacitors and thus may be dictated by their shape and size.

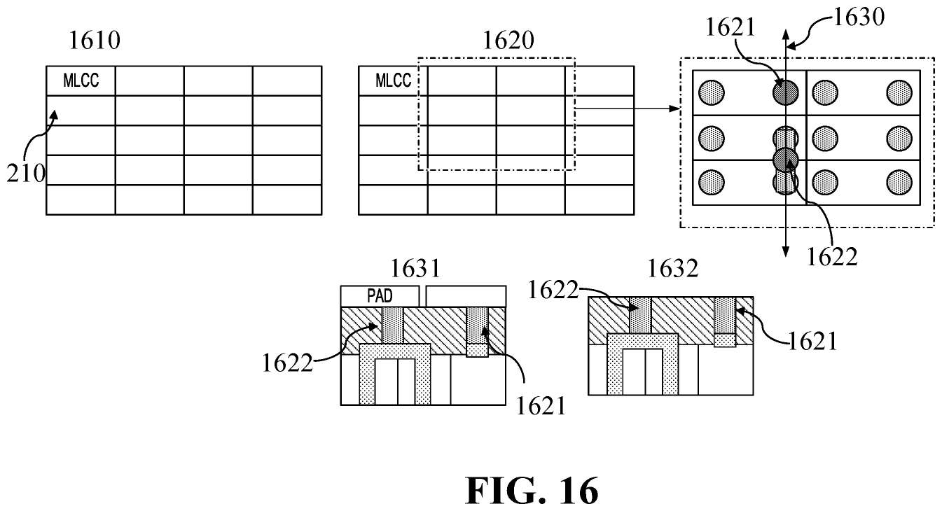

FIG. 16 shows an example of how an MLCC sheet may be cut and individual capacitors contacted to create an MLCC-based substrate, consistent with embodiments of the present disclosure. Block 1610 shows a sheet as fabricated including a plurality of MLCC capacitors 210. Each of the capacitors may be attached to its neighboring capacitors and thus, in order to obtain a subsection 1620 of the MLCC sheet 1610, the sheet may require cutting along the capacitor borders (e.g., diamond sawing, laser sawing, etc.). Subsection 1620 of the MLCC sheet 1610 may provide a basis for the MLCC-based substrate, and therefore may require deposition of RDL and formation of contacts to individual capacitors. Cross-section 1630 traverses three separate MLCC capacitors, demonstrating two examples 1631 and 1632 of how these MLCCs may be contacted. Depending on the coupling method, metal pads may be deposited on top of Cu plugs 1621 and 1622, as shown in cutline 1631. Such method of contacting may be suitable for soldering or thermo-compressive bonding. Alternatively, the Cu plugs 1621 and 1622 may be used directly for hybrid bonding (see cutline 1632) omitting addition pad deposition on top of the plugs.

The substrate based on MLCC array thus prepared may be ready for the subsequent steps of the process, which may involve coupling an integrated circuit (IC) to the MLCC-based substrate, such that the IC may be coupled to the MLCC-based substrate by at least one solder bump or copper pillar on the at least one pad. Coupling of the MLCC-based substrate may be performed in a similar way to the methods described with respect to the resin-based substrate. The pads of the IC and the substrate may need to be aligned and the bonding may be performed by soldering, thermo-compressive bonding or hybrid bonding, ultimately resulting in the connection between the two target interfaces, where the IC may be electrically coupled to at least one MLCC of the plurality of MLCCs.

Both resin-based and MLCC-based substrates may be coupled to the chip using identical processes and procedures. Each of the proposed substrate embodiments may perform structurally very similar functions, providing a base onto which a IC may be coupled to achieve reduced module area, improved thermal management, and sturdier structural support for the thinned chip in addition to electrical functions required of constituent passive components. For the above reasons, the methods of coupling of the IC to the MLCC-based substrate may be considered equivalent to the methods describe in the preceding sections concerning the resin-based substrate.

In some embodiments, soldering results in module thickness that may exceed vertical dimensions required for the intended application. The MLCC-based substrate and the IC may therefore be bonded such that the coupling the IC to the MLCC-based substrate comprises thermo-compression bonding. This method may involve alignment of corresponding pillars on the resin-based substrate and the chip as described above. Subsequently, the bonding may involve application of compressive force bringing the two units together at elevated temperatures. Depending on metals present in the pillars, the temperatures required for bonding may exceed 300° C.

In following steps of the process, the gaps created in between the bonded bumps be filled by forming an underfill between the IC and the MLCC-based substrate. The process of forming the underfilling may involve introduction of a low-viscosity adhesive to fill the voids in between the bonded bumps. Elevated temperature may be applied to reduce the viscosity of such adhesive and provide additional support for the interface, in anticipation of applied thermo-mechanical stress in the following processing steps, for example grinding, polishing or any other step performed on the bonded module, or during operation.

In some embodiments, coupling the IC to the MLCC-based substrate may include hybrid bonding for further reduction in the thickness of the interface between the MLCC-based substrate and the IC. Hybrid bonding may take place between at least one pillar of the IC and at least one pillar embedded in the insulating layer, which may constitute part of the RDL layer formed in the previous process step. As described above, prior to bonding each interface may be coated with a thin oxide layer and planarized to reduce the surface roughness to the degree required for initial van der Waals bonding between the adjacent surfaces. Upon application of elevated temperature, copper diffusion and oxide-to-oxide adhesive bonding create strong and thin interface between the MLCC-based substrate and the IC.

In some embodiments, preparation of the module of reduced surface area may further comprise grinding the IC to 50 μm. Grinding may be necessary to reduce the module height, but it may also serve as a step in preparation for introduction of measures for improved thermal management. In such cases, the IC may be configured to transfer heat directly to a heat sink. The heat sink may comprise an active heat sink or a passive heat sink and may be brought into contact with the IC to facilitate more effective heat extraction from the areas of increased heat dissipation.

Similar to the resin-based substrate, the module based on the MLCC array substrate may require connecting to external electrical components. The module may therefore be attached to the PCB by methods described above. For example, in one embodiment this may include forming a bump on a side of the MLCC-based substrate that may be opposite to a side of the RDL and coupling the MLCC-based substrate to a printed circuit board (PCB) by the bump. In another embodiment, the coupling may include coupling the MLCC-based substrate to a printed circuit board (PCB) by a wire, as shown on the example of FIG. 14.

A charge MLCC-based charge pump module manufactured based on the embodiments described above may be packaged. A package thus created may comprise a MLCC-based substrate comprising a plurality of MLCCs embedded in a resin, wherein each MLCC of the plurality of MLCCs directly contacts another MLCC, forming a redistribution layer (RDL) in an insulating layer on the MLCC-based substrate and an integrated circuit (IC) coupled to the MLCC-based substrate by soldering, thermos-compression or hybrid bonding methods. The packaged module may comprise electrical connections for easy of integration with external components and may additionally be equipped with components for improved thermal performance of the module.

The methods described above relate to coupling of a resin-based or an MLCC-based substrate to the IC. However, one skilled in the art will recognize that these techniques may be applied to other substrates prepared according to the teachings of the present disclosure. Likewise, although coupling of only one IC has been described, the above techniques may also be applicable for bonding multiple ICs to the elected substrate. In some embodiments, a plurality of ICs may be bonded to the substrate one next to the other. In other embodiments, the ICs may be stacked on top of one another, in a manner similar to 3D integrated circuits.

The foregoing description has been presented for purposes of illustration. It is not exhaustive and is not limited to the precise forms or embodiments disclosed. Modifications and adaptations will be apparent to those skilled in the art from consideration of the specification and practice of the disclosed embodiments. The disclosed embodiments may be further described via the clauses set forth below:

Further non-limiting features of the disclosure are set out in the below clauses:
1. A method for fabricating a module with reduced area, comprising forming a resin-based substrate by attaching a plurality of multilayer ceramic capacitors (MLCCs) to a base sheet; molding resin around the base sheet; and performing one of: (a) removing the base sheet and adding a redistribution layer (RDL) at surfaces of the plurality of MLCCs from which the base sheet is removed; or (b) grinding the molded resin to surfaces of the plurality of MLCCs opposite to surfaces of the plurality of MLCCs facing the base sheet; forming the RDL in an insulating layer on the resin-based substrate; and coupling an integrated circuit (IC) to the resin-based substrate.
2. The method of clause 1, wherein the resin comprises an epoxy.
3. The method of clause 1, wherein the insulating layer comprises a polyimide or an oxide.
4. The method of clause 1, wherein at least two MLCCs of the plurality of MLCCs are electrically coupled to each other.
5. The method of clause 1, wherein one of the MLCCs has a voltage rating that is different from that of another of the MLCCs.
6. The method of clause 1, further comprising forming at least one pad on the RDL.
7. The method of clause 6, wherein the IC is coupled to the resin-based substrate by at least one solder bump or copper pillar on the at least one pad.
8. The method of clause 6, wherein the RDL comprises a first passivation layer and the at least one pad is on the first passivation layer.
9. The method of clause 8, wherein the RDL comprises a second passivation layer and the at least one pad is between the first passivation layer and the second passivation layer.
10. The method of clause 1, wherein the IC is electrically coupled to at least one MLCC of the plurality of MLCCs.
11. The method of clause 1, wherein coupling the IC to the resin-based substrate comprises thermo-compression bonding.
12. The method of clause 1, wherein coupling the IC to the resin-based substrate comprises hybrid bonding.
13. The method of clause 12, wherein the hybrid bonding is between at least one plug of the IC and at least one plug embedded in the insulating layer.
14. The method of clause 1, wherein coupling the IC to the resin-based substrate comprises connecting the IC to the resin-based substrate with a wire.
15. The method of clause 1, further comprising grinding the IC to 50 μm.
16. The method of clause 1, further comprising forming a bump on a side of the resin-based substrate that is opposite to a side of the RDL.
17. The method of clause 16, further comprising coupling the resin-based substrate to a printed circuit board (PCB) by the bump.
18. The method of clause 1, further comprising coupling the resin-based substrate to a printed circuit board (PCB) by a wire.
19. The method of clause 1, comprising forming an underfill between the IC and the resin-based substrate.
20. The method of clause 1, wherein the IC is configured to transfer heat directly to a heat sink.
21. The method of clause 1, further comprising forming at least one via to extend through the resin.
22. The method of clause 1, further comprising forming at least one via to extend through the IC
23. The method of clause 1, further comprising forming an oxide layer prior to coupling the IC to the resin-based substrate.
24. The method of clause 1, further comprising performing chemical mechanical planarization (CMP) prior to coupling the IC to the resin-based substrate.
25. The method of clause 1, wherein forming the RDL comprises: depositing the insulating layer on the resin-based substrate; forming at least one hole in the insulating layer; and depositing a metal layer on the insulating layer.
26. The method of clause 1, wherein coupling the IC to the resin-based substrate comprises at least one of: a) forming a plurality of copper pillars on the RDL; building the plurality of copper pillars on the IC; performing face-to-face thermocompression bonding between the resin-based substrate and the IC; or b) forming a plug on the IC and forming a plug on at least one MLCC of the plurality of MLCCs; planarizing the resin-based substrate and the IC; and performing face-to-face hybrid bonding between the resin-based substrate and the IC.
27. A method for fabricating a module with reduced area, comprising: forming a resin-based substrate; forming a redistribution layer (RDL) on the resin-based substrate by: depositing an insulating layer on the resin-based substrate; forming at least one hole in the insulating layer; and depositing a metal layer on the insulating layer; and coupling an integrated circuit (IC) to the resin-based substrate.
28. The method of clause 27, wherein forming the resin-based substrate comprises: attaching a plurality of multilayer ceramic capacitors (MLCCs) to a base sheet; molding resin around the base sheet; and performing one of: (a) removing the base sheet and adding the RDL at surfaces of the plurality of MLCCs from which the base sheet is removed; or (b) grinding the molded resin to surfaces of the plurality of MLCCs opposite to surfaces of the plurality of MLCCs facing the base sheet.
29. The method of clause 27, wherein coupling the IC to the resin-based substrate comprises at least one of: a) forming a plurality of copper pillars on the RDL; building the plurality of copper pillars on the IC; performing face-to-face thermocompression bonding between the resin-based substrate and the IC; or b) forming a plug on the IC and forming a plug on at least one MLCC of the plurality of MLCCs; planarizing the resin-based substrate and the IC; and performing face-to-face hybrid bonding between the resin-based substrate and the
30. A method for fabricating a module with reduced area, comprising one of: a) forming a resin-based substrate by forming a resin on a plurality of multilayer ceramic capacitors (MLCCs); forming a redistribution layer (RDL) in an insulating layer on the resin-based substrate; and coupling an integrated circuit (IC) to the resin-based substrate by: forming a plurality of copper pillars on the RDL; building the plurality of copper pillars on the IC; performing face-to-face thermocompression bonding between the resin-based substrate and the IC; or b) forming a plug on the IC and forming a plug on at least one MLCC of the plurality of MLCCs; planarizing the resin-based substrate and the IC; and performing face-to-face hybrid bonding between the resin-based substrate and the IC.
31. The method of clause 30, wherein forming the resin-based substrate comprises: attaching the plurality of multilayer ceramic capacitors (MLCCs) to a base sheet; molding the resin around the base sheet; and performing one of: (a) removing the base sheet and adding the RDL at surfaces of the plurality of MLCCs from which the base sheet is removed; or (b) grinding the molded resin to surfaces of the plurality of MLCCs opposite to surfaces of the plurality of MLCCs facing the base sheet.
32. The method of clause 30, wherein forming the RDL comprises: depositing the insulating layer on the resin-based substrate; forming at least one hole in the insulating layer; and depositing a metal layer on the insulating layer.
33. A package with reduced area, comprising: a resin-based substrate comprising a plurality of multilayer ceramic capacitors (MLCCs) embedded in a resin; a redistribution layer (RDL) in an insulating layer on the resin-based substrate; an integrated circuit (IC) coupled to the resin-based substrate.
34. A method comprising: forming a MLCC-based substrate by forming a resin on a plurality of multilayer ceramic capacitors (MLCCs), wherein each MLCC of the plurality of MLCCs directly contacts another MLCC; forming a redistribution layer (RDL) in an insulating layer on the MLCC-based substrate; coupling an integrated circuit (IC) to the MLCC-based substrate.
35. The method of clause 34, wherein the resin comprises an epoxy.
36. The method of clause 34, wherein the insulating layer comprises a polyimide or an oxide.
37. The method of clause 34, wherein at least two MLCCs of the plurality of MLCCs are electrically coupled to each other.
38. The method of clause 34, wherein the plurality of MLCCs have a same voltage rating.
39. The method of clause 34, further comprising forming at least one pad on the RDL.
40. The method of clause 39, wherein the IC is coupled to the MLCC-based substrate by at least one solder bump or copper pillar on the at least one pad.
41. The method of clause 39, wherein the RDL comprises a first passivation layer and the at least one pad is on the first passivation layer.
42. The method of clause 41, wherein the RDL comprises a second passivation layer and the at least one pad is between the first passivation layer and the second passivation layer.
43. The method of clause 34, wherein the IC is electrically coupled to at least one MLCC of the plurality of MLCCs.
44. The method of clause 34, wherein coupling the IC to the MLCC-based substrate comprises thermo-compression bonding.
45. The method of clause 34, wherein coupling the IC to the MLCC-based substrate comprises hybrid bonding.
46. The method of clause 45, wherein the hybrid bonding is between at least one plug of the IC and at least one plug embedded in the insulating layer.
47. The method of clause 34, wherein coupling the IC to the MLCC-based substrate comprises connecting the IC to the MLCC-based substrate with a wire.
48. The method of clause 34, further comprising grinding the IC to 50 μm.
49. The method of clause 34, further comprising forming a bump on a side of the MLCC-based substrate that is opposite to a side of the RDL.
50. The method of clause 49, further comprising coupling the MLCC-based substrate to a printed circuit board (PCB) by the bump.
51. The method of clause 34, further comprising coupling the MLCC-based substrate to a printed circuit board (PCB) by a wire.
52. The method of clause 34, comprising forming an underfill between the IC and the MLCC-based substrate.
53. The method of clause 34, wherein the IC is configured to transfer heat directly to a heat sink.
54. The method of clause 34, further comprising cutting the MLCC-based substrate.
55. A package comprising: a MLCC-based substrate comprising a plurality of multilayer ceramic capacitors (MLCCs) embedded in a resin, wherein each MLCC of the plurality of MLCCs directly contacts another MLCC; forming a redistribution layer (RDL) in an insulating layer on the MLCC-based substrate; an integrated circuit (IC) coupled to the MLCC-based substrate.

It will be appreciated that the embodiments of the present disclosure are not limited to the exact construction that has been described above and illustrated in the accompanying drawings, and that various modifications and changes may be made without departing from the scope thereof.

Various embodiments of the invention can be implemented to meet a wide variety of specifications. Unless otherwise noted above, selection of suitable component values is a matter of design choice. Various embodiments of the invention may be implemented in any suitable integrated circuit (IC) technology (including but not limited to MOSFET structures), or in hybrid or discrete circuit forms. Integrated circuit embodiments may be fabricated using any suitable substrates and processes, including but not limited to standard bulk silicon, high-resistivity bulk CMOS, silicon-on-insulator (SOI), and silicon-on-sapphire (SOS). Unless otherwise noted above, embodiments of the invention may be implemented in other transistor technologies such as bipolar, BiCMOS, LDMOS, BCD, GaAs HBT, GaN HEMT, GaAs pHEMT, and MESFET technologies. However, embodiments of the invention are particularly useful when fabricated using an SOI or SOS based process, or when fabricated with processes having similar characteristics. Fabrication in CMOS using SOI or SOS processes enables circuits with low power consumption, the ability to withstand high power signals during operation due to FET stacking, good linearity, and high frequency operation (i.e., radio frequencies up to and exceeding 300 GHz). Monolithic IC implementation is particularly useful since parasitic capacitances generally can be kept low (or at a minimum, kept uniform across all units, permitting them to be compensated) by careful design.

Voltage levels may be adjusted, and/or voltage and/or control signal polarities reversed, depending on a particular specification and/or implementing technology (e.g., NMOS, PMOS, or CMOS, and enhancement mode or depletion mode transistor devices). Component voltage, current, and power handling capabilities may be adapted as needed, for example, by adjusting device sizes, serially “stacking” components (particularly FETs) to withstand greater voltages, and/or using multiple components in parallel to handle greater currents. Additional circuit components may be added to enhance the capabilities of the disclosed circuits and/or to provide additional functionality without significantly altering the functionality of the disclosed circuits.

Circuits and devices in accordance with the present invention may be used alone or in combination with other components, circuits, and devices. Embodiments of the present invention may be fabricated as integrated circuits (ICs), which may be encased in IC packages and/or in modules for ease of handling, manufacture, and/or improved performance. In particular, IC embodiments of this invention are often used in modules in which one or more of such ICs are combined with other circuit components or blocks (e.g., filters, amplifiers, passive components, and possibly additional ICs) into one package. The ICs and/or modules are then typically combined with other components, often on a printed circuit board, to form part of an end product such as a cellular telephone, laptop computer, or electronic tablet, or to form a higher-level module which may be used in a wide variety of products, such as vehicles, test equipment, medical devices, etc. Through various configurations of modules and assemblies, such ICs typically enable a mode of communication, often wireless communication.

Some or all aspects of the invention may be implemented in hardware or software, or a combination of both (e.g., programmable logic arrays). Unless otherwise specified, the methods included as part of the invention are not inherently related to any particular computer or other apparatus. In particular, various general purpose computing machines may be used with programs written in accordance with the teachings herein, or it may be more convenient to use a special purpose computer or special-purpose hardware (such as integrated circuits) to perform particular functions. Thus, embodiments of the invention may be implemented in one or more computer programs (i.e., a set of instructions or codes) executing on one or more programmed or programmable computer systems (which may be of various architectures, such as distributed, client/server, or grid) each comprising at least one processor, at least one data storage system (which may include volatile and non-volatile memory and/or storage elements), at least one input device or port, and at least one output device or port. Program instructions or code are applied to input data to perform the functions described herein and generate output information. The output information is applied to one or more output devices, in known fashion.

Each such computer program may be implemented in any desired computer language (including machine, assembly, or high level procedural, logical, object oriented programming languages or a custom language/script) to communicate with a computer system, and may be implemented in a distributed manner in which different parts of the computation specified by the software are performed by different processors. In any case, the computer language may be a compiled or interpreted language. Computer programs implementing some or all of the invention may form one or more modules of a larger program or system of programs. Some or all of the elements of the computer program can be implemented as data structures stored in a computer readable medium or other organized data conforming to a data model stored in a data repository.

Each such computer program may be stored on or downloaded to (for example, by being encoded in a propagated signal and delivered over a communication medium such as a network) a tangible, non-transitory storage media or device (e.g., solid state memory media or devices, or magnetic or optical media) for a period of time (e.g., the time between refresh periods of a dynamic memory device, such as a dynamic RAM, or semi-permanently, or permanently), the storage media or device being readable by a general or special purpose programmable computer for configuring and operating the computer when the storage media or device is read by the computer system to perform the procedures described above. The inventive system may also be considered to be implemented as a non-transitory computer-readable storage medium, configured with a computer program, where the storage medium so configured causes a computer system to operate in a specific or predefined manner to perform the functions described above.

The foregoing detailed description refers to exemplary embodiments, examples of which are illustrated in the accompanying drawings. Wherever possible, the same reference numbers are used in the drawings and the following description to refer to the same or similar parts. While several illustrative embodiments are described herein, modifications, adaptations and other implementations are possible. The implementations set forth in the following description of exemplary embodiments do not represent all implementations consistent with the disclosure. Instead, they are merely examples of apparatuses and methods consistent with aspects related to the subject matter recited in the appended claims. Other features, objects, and advantages of the invention will be apparent from the description and drawings, and from the claims. For example, substitutions, additions, or modifications may be made to the components and steps illustrated in the drawings, and the illustrative methods described herein may be modified by substituting, reordering, removing, or adding steps to the disclosed methods. Accordingly, the foregoing detailed description is not limited to the disclosed embodiments and examples. The proper scope of the invention may be defined by the appended claims.

Although the terms “first,” “second,” etc., may be used herein to describe various elements, these elements should not be limited by these terms. These terms are used to distinguish one element from another. For example, a first element could be termed a second element, and, similarly, a second element could be termed a first element, without departing from the scope of the embodiments.

It is appreciated that the figures have not necessarily been drawn to scale, such as for simplicity and/or clarity of illustration. For example, dimensions of some aspects may be exaggerated relative to others. Further, it is appreciated that other embodiments may be utilized. Furthermore, structural and/or other changes may be made without departing from claimed subject matter. References throughout this specification to “subject matter” refer to subject matter intended to be covered by one or more implementations, or any portion thereof, and are not necessarily intended to refer to a complete implementation, to a particular combination of implementation, or to any portion thereof. It is also noted that directions and/or references, for example, such as up, down, top, bottom, and so on, may be used to facilitate discussion of drawings and are not intended to restrict application of particular subject matter. Therefore, the following detailed description is not to be taken to limit subject matter and/or equivalents thereof.

References throughout this specification to one implementation, an implementation, one embodiment, an embodiment, and/or the like means that a particular feature, structure, characteristic, and/or the like described in relation to a particular implementation and/or embodiment is included in at least one implementation and/or embodiment of subject matter. Thus, appearances of such phrases, for example, in various places throughout this specification are not necessarily intended to refer to the same implementation and/or embodiment or to any one particular implementation and/or embodiment. Furthermore, it is appreciated that particular features, structures, characteristics, and/or the like described are capable of being combined in various ways in one or more implementations and/or embodiments and, therefore, are within intended scope. In general, of course, as has always been the case for the specification of a patent application, these and other issues have a potential to vary in a particular context of usage. In other words, throughout the disclosure, particular context of description and/or usage provides helpful guidance regarding reasonable inferences to be drawn; however, likewise, “in this context” in general without further qualification refers at least to the context of the present patent application.

In the context of the present patent application, the term “connection,” the term “component” and/or similar terms are intended to be physical, but are not necessarily always tangible. Whether or not these terms refer to tangible subject matter, thus, may vary in a particular context of usage. As an example, a tangible connection and/or tangible connection path may be made, such as by a tangible, electrical connection, such as an electrically conductive path comprising metal or other conductor, that is able to conduct electrical current between two tangible components. Likewise, a tangible connection path may be at least partially affected and/or controlled, such that, as is typical, a tangible connection path may be open or closed, at times resulting from influence of one or more externally derived signals, such as external currents and/or voltages, such as for an electrical switch. Nonlimiting illustrations of an electrical switch include a transistor, a diode, etc. However, a “connection” and/or “component,” in a particular context of usage, likewise, although physical, can also be non-tangible, such as a connection between a client and a server over a network, particularly a wireless network, which generally refers to the ability for the client and server to transmit, receive, and/or exchange communications, as discussed in more detail later.

In a particular context of usage, such as a particular context in which tangible components are being discussed, therefore, the terms “coupled” and “connected” are used in a manner so that the terms are not synonymous. Similar terms may also be used in a manner in which a similar intention is exhibited. Thus, “connected” is used to indicate that two or more tangible components and/or the like, for example, are tangibly in direct physical contact. Thus, using the previous example, two tangible components that are electrically connected are physically connected via a tangible electrical connection, as previously discussed. However, “coupled,” is used to mean that potentially two or more tangible components are tangibly in direct physical contact. Nonetheless, “coupled” is also used to mean that two or more tangible components and/or the like are not necessarily tangibly in direct physical contact, but are able to co-operate, liaise, and/or interact, such as, for example, by being “optically coupled.” Likewise, the term “coupled” is also understood to mean indirectly connected. It is further noted, in the context of the present patent application, since memory, such as a memory component and/or memory states, is intended to be non-transitory, the term physical, at least if used in relation to memory necessarily implies that such memory components and/or memory states, continuing with the example, are tangible.

As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

In the foregoing description, various aspects of claimed subject matter have been described. For purposes of explanation, specifics, such as amounts, systems and/or configurations, as examples, were set forth. In other instances, well-known features were omitted and/or simplified so as not to obscure claimed subject matter. While certain features have been illustrated and/or described herein, many modifications, substitutions, changes and/or equivalents will now occur to those skilled in the art. It is, therefore, to be appreciated that the appended claims are intended to cover all modifications and/or changes as fall within claimed subject matter.

It is to be appreciated that the foregoing description is intended to illustrate and not to limit the scope of the invention, which is defined by the scope of the following claims, and that other embodiments are within the scope of the claims. In particular, the scope of the invention includes any and all feasible combinations of one or more of the processes, machines, manufactures, or compositions of matter set forth in the claims below. Therefore, even if some or all of the dependent claims have been written with single dependency, it is to be appreciated that the present application provides full support for such claims to be multiply dependent on some or all of the other claims. (Note that the parenthetical labels for claim elements are for ease of referring to such elements, and do not in themselves indicate a particular required ordering or enumeration of elements; further, such labels may be reused in dependent claims as references to additional elements without being regarded as starting a conflicting labeling sequence).

What is claimed is:

1. A method comprising:
forming a MLCC-based substrate by forming a resin on a plurality of multilayer ceramic capacitors (MLCCs), wherein each MLCC of the plurality of MLCCs directly contacts another MLCC;
forming a redistribution layer (RDL) in an insulating layer on the MLCC-based substrate;
coupling an integrated circuit (IC) to the MLCC-based substrate.

2. The method of claim 1, wherein the resin comprises an epoxy.

3. The method of claim 1, wherein the insulating layer comprises a polyimide or an oxide.

4. The method of claim 1, wherein at least two MLCCs of the plurality of MLCCs are electrically coupled to each other.

5. The method of claim 1, wherein the plurality of MLCCs have a same voltage rating.

6. The method of claim 1, further comprising forming at least one pad on the RDL.

7. The method of claim 6, wherein the IC is coupled to the MLCC-based substrate by at least one solder bump or copper pillar on the at least one pad.

8. The method of claim 6, wherein the RDL comprises a first passivation layer and the at least one pad is on the first passivation layer.

9. The method of claim 8, wherein the RDL comprises a second passivation layer and the at least one pad is between the first passivation layer and the second passivation layer.

10. The method of claim 1, wherein the IC is electrically coupled to at least one MLCC of the plurality of MLCCs.

11. The method of claim 1, wherein coupling the IC to the MLCC-based substrate comprises thermo-compression bonding.

12. The method of claim 1, wherein coupling the IC to the MLCC-based substrate comprises hybrid bonding.

13. The method of claim 12, wherein the hybrid bonding is between at least one plug of the IC and at least one plug embedded in the insulating layer.

14. The method of claim 1, wherein coupling the IC to the MLCC-based substrate comprises connecting the IC to the MLCC-based substrate with a wire.

15. The method of claim 1, further comprising grinding the IC to 50 μm.

16. The method of claim 1, further comprising forming a bump on a side of the MLCC-based substrate that is opposite to a side of the RDL.

17. The method of claim 16, further comprising coupling the MLCC-based substrate to a printed circuit board (PCB) by the bump.

18. The method of claim 1, further comprising coupling the MLCC-based substrate to a printed circuit board (PCB) by a wire.

19. The method of claim 1, comprising forming an underfill between the IC and the MLCC-based substrate.

20. The method of claim 1, wherein the IC is configured to transfer heat directly to a heat sink.

21. The method of claim 1, further comprising cutting the MLCC-based substrate.

22. A package comprising:
a MLCC-based substrate comprising a plurality of multilayer ceramic capacitors (MLCCs) embedded in a resin, wherein each MLCC of the plurality of MLCCs directly contacts another MLCC;
forming a redistribution layer (RDL) in an insulating layer on the MLCC-based substrate;
an integrated circuit (IC) coupled to the MLCC-based substrate.
